(19) United States
(12) Patent Application Publication
(10) Pub. No.: US 2025/0055262 A1
(43) Pub. Date: Feb. 13, 2025

(54) LASER AND LIGHT GUIDE SYSTEM AND MANUFACTURING METHOD THEREOF

(71) Applicants: TOPGAN SP. Z 0.0., Warszawa (PL); INSTYTUT WYSOKICH CISNIEN POLSKIEJ AKADEMII NAUK, Warszawa (PL)

(72) Inventors: Anna KAFAR, Gdynia (PL); Kiran SABA, Shorkot (PK); Krzysztof GIBASIEWICZ, Warszawa (PL); Szymon STANCZYK, Gdynia (PL); Stephen NAJDA, Warszawa (PL); Piotr PERLIN, Warszawa (PL)

(21) Appl. No.: 18/712,575

(22) PCT Filed: Nov. 28, 2022
(86) PCT No.: PCT/PL2022/050085

§ 371 Date: May 22, 2024

(30) Foreign Application Priority Data
Nov. 26, 2021 (PL) P.439657

(51) Int. Cl. H01S 5/343; H01S 5/22

(52) U.S. Cl. CPC H01S 5/34333; H01S 5/22

(57) ABSTRACT

The subject of the invention is the method for manufacturing a laser and light guide system comprising the following steps: a gallium nitride substrate is formed, after which regions with increased disorientation in relation to their surroundings are defined on the gallium nitride substrate, a bottom cladding layer is deposited, a bottom light guide layer is deposited, a light-emitting layer is deposited, a non-doped upper light guide layer is deposited, an electron blocking layer is deposited, an upper light guide layer is deposited, an upper cladding layer is deposited, an subcontact layer is deposited, a spatial structure of a light guide in a shape of a ridge is formed, an aperture separating the laser and the light guide is formed, forming one of the laser mirrors, wherein the light guide is formed out of the same layers as the laser structure, whereas the quantum wells in the light guide region comprise at least 3.5 mol % less indium compared to the laser region, and the optical absorption of laser light in the light guide is lower than 12 cm⁻¹. Another subject of the invention is a laser and light guide system.

The present invention relates to a laser and light guide system and a method for manufacturing an integrated laser and light guide system using III-N semiconductors. The invention finds application in optoelectronics.

From US Patent Application US2014376857A1, a photonic integrated circuit is known, which may include a silicon layer comprising a waveguide and at least one other photonic element. The photonic integrated circuit may also comprise a first insulating region located above the first side of the silicon layer and surrounding at least one level of metallization, a second insulating region located above the second side of the silicon layer and surrounding at least one agent amplifying a laser source optically coupled to a waveguide.

From US Patent U.S. Ser. No. 10/026,723B2, a photonic integrated circuit chip is known, comprising a lumped active optical element, an electrode configured to receive an electrical signal, where at least one characteristic of the lumped active optical element is changed based on the electrical signal received by the electrode, a ground electrode, and a bond contact electrically coupled to the electrode, and an interposer bonded to at least a portion of the photonic integrated circuit chip, wherein the interposer includes a conductive trace formed on a surface of the interposer, the conductive trace electrically coupled to a source of the electrical signal, a ground trace, and a conductive via bonded with the bond contact of the photonic integrated circuit chip, wherein the conductive via is electrically coupled to the conductive trace to provide the electrical signal to the electrode of the photonic integrated circuit chip.

From European Patent EP2567004B1, a substrate is known, consisting of an assembly of neighbouring flat surfaces in a form of stripes having a width of 1 to 2000 μm. The longer edges of all of the flat surfaces are parallel to each other, and their planes are disoriented in relation to the crystallographic plane of gallium nitride crystal defined by Miller-Bravais indices (0001), (10-10), (11-22), or (11-20). The disorientation angle of each of the flat surfaces is between 0 and 3 degrees and is different for each pair of neighbouring flat surfaces. The substrate according to the invention allows epitaxial growth of a layered AlInGaN structure using MOCVD or MBE epitaxial growth method, which allows manufacturing a laser diode with non-absorbing mirrors, emitting light with a wavelength of 380 to 550 nm, and a laser diode array which emits light with various wavelengths in the range of 380 to 550 nm, simultaneously.

From Polish Patent Pat. 228006, a superluminescent diode based on an AlInGaN alloy is known, comprising a gallium nitride bulk substrate, a bottom cladding layer with n-type electrical conductivity, a bottom light guide layer with n-type electrical conductivity, a light-emitting layer, an electron blocking layer with p-type electrical conductivity, an upper light guide layer, an upper cladding layer with p-type electrical conductivity, and a subcontact layer with p-type electrical conductivity, wherein the gallium nitride bulk substrate has a spatially variable disorientation of the surface in relation to the crystallographic plane M in range of 0° to 10°.

Photonic integrated circuits (PICs) are becoming an increasingly important component in modern optoelectronics. Their size, ease of use, resistance to overloads and multifunctionality are the reasons for increasing penetration of the market by these systems. The first photonic integrated circuits have been developed on a silicon platform and they typically operate in the 1.55 μm telecommunication band. The problem of silicon photonics is the fundamental difficulty in integrating emitters (lasers) on a common platform, because silicon is a semiconductor with an indirect energy gap and is not able emit light by itself. Silicon based PICs always require external light sources. The InP platform allows integration of emitters and waveguides on a single substrate, but limits the systems to operation in mid-infrared. The fundamental problem of fully integrated visible-range PICs is combining lasers with passive elements, such as waveguides, formed on a substrate which is transparent to light. The problem is not only the leakage of light into the substrate, but also the development of a concept of a light guide with a high coupling coefficient to the laser light source.

The aim of the presented invention was to develop a system operating in the visible light range. Such systems are needed, among others, for optical atomic clocks. To produce visible light in a wide range, semiconductors based on AlInGaN (aluminium-indium-gallium nitride) should be used. Lasers built from these materials are usually manufactured on a gallium nitride substrate.

Unexpectedly, all technical problems mentioned above have been solved by the present invention.

The object of the invention is the method for manufacturing a laser and light guide system comprising the following steps:
a) a gallium nitride bulk substrate is formed, after which regions with increased disorientation in relation to their surroundings are defined on the gallium nitride substrate,
b) a bottom cladding layer with n-type electrical conductivity is deposited,
c) a bottom light guide layer with n-type electrical conductivity is deposited,
d) a light-emitting layer is deposited, comprised of a single or a multiple quantum well made of a compound with a formula of InₓGa₁₋ₓN,
e) a non-doped upper light guide layer is deposited,
f) an electron blocking layer with p-type electrical conductivity is deposited,
g) an upper light guide layer with p-type electrical conductivity is deposited,
h) an upper cladding layer with p-type electrical conductivity is deposited,
i) a subcontact layer with p-type electrical conductivity is deposited,
j) a spatial structure of a light guide in a shape of a ridge is formed,
k) an aperture separating the laser and the light guide is formed, forming one of the laser mirrors, characterised in that the light guide is formed out of the same layers as the laser structure, whereas the quantum wells in the light guide region comprise at least 3.5 mol % less indium compared to the laser region, and the optical absorption of laser light in the light guide is lower than 12 cm⁻¹.

Preferably, the method is characterised in that the disorientation profile of the gallium nitride substrate in the aperture region, between the laser mirror and the light guide entry window, is defined by equation:

$${δ}_{lok} ( x ) = {δ}_{1} + \frac{{δ}_{2} - {δ}_{1}}{1 + Exp ( \frac{{a}_{d} ( x - d )}{d} )}$$

where,
δ₁—indicates the value of the disorientation angle of the substrate present in the laser region,
δ₂—indicates the value of the disorientation angle of the substrate present in the light guide region,
d—indicates the width of the aperture,
x—indicates the spatial coordinate in the aperture between the laser and the light guide,
a_{d}—indicates a coefficient specifying the change profile, comprised in range of 3 to 7.

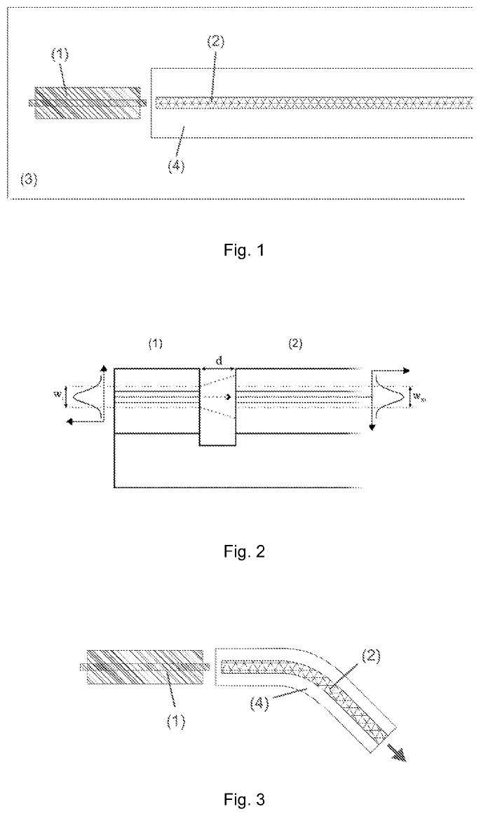

Preferably, the method is characterised in that the disorientation of the gallium nitride substrate in the light guide region, 4 in FIG. 1, is higher than the basic disorientation of the gallium nitride substrate and is defined by equation:

$${δ}_{2} > \frac{{a}_{1} {δ}_{1} + 0.05 {a}_{2} - 20}{0.43 {a}_{1}}$$

where,
δ₁—indicates the value of the disorientation angle of the substrate present in the laser region,
δ₂—indicates the value of the disorientation angle of the substrate present in the light guide region,
a₁ and a₂—indicate parameters depending on the growth conditions of the layers and describing the linear approximation of the relationship between the emission wavelength of the structure and the disorientation angle δ₁.

Preferably, the method is characterised in that the width of the aperture between the laser mirror and the light guide entry window, FIG. 2, is defined by equation:

$$d < ( 1.5 {w}_{m} - 0.5 {w}_{l} ) / Tan ( \frac{2 λ}{π {w}_{l}} )$$

where,
d—indicates the width of the aperture,
wₗ and wₘ—indicate the optical mode width in the transverse direction in the laser region and in the light guide region, respectively,
λ—indicates the emission wavelength of the laser.

Preferably, the method is characterised in that the aperture walls on the side of the laser are coated with optical layers with light reflection coefficient values in range of 0.1-100%.

Preferably, the method is characterised in that the aperture walls on the side of the light guide are coated with optical layers with light reflection coefficient values below 1%.

Preferably, the method is characterised in that the light guide having a bent shape is formed—FIG. 3.

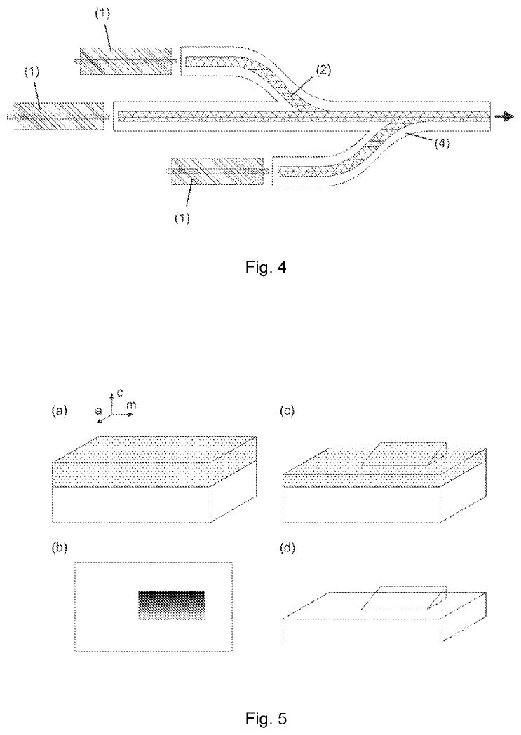

Preferably, the method is characterised in that, on the gallium nitride substrate, a structure is formed comprising at least two lasers with light guides, wherein the light guides are combined into one main light guide—FIG. 4.

Another object of the invention is a laser and light guide system comprising, sequentially, a structured gallium nitride bulk substrate, on which regions with increased disorientation in relation to their surroundings are defined, a bottom cladding layer with n-type electrical conductivity, a bottom light guide layer with n-type electrical conductivity, a light-emitting layer comprised of a single or a multiple quantum well made of a compound with a formula of InₓGa₁₋ₓN, a non-doped upper light guide layer, an electron blocking layer with p-type electrical conductivity, an upper light guide layer with p-type electrical conductivity, an upper cladding layer with p-type electrical conductivity, a subcontact layer with p-type electrical conductivity, a spatial structure of a light guide in a shape of a ridge, an aperture separating the laser and the light guide, forming one of the laser mirrors, characterised in that the light guide comprises the same layers as the laser structure, wherein the quantum wells in the light guide region comprise at least 3.5 mol % less indium compared to the laser region, and the optical absorption of laser light in the light guide is lower than 12 cm⁻¹.

Preferably, the system is characterised in that the disorientation profile of the gallium nitride substrate in the aperture region, between the laser mirror and the light guide entry window, is defined by equation:

$${δ}_{lok} ( x ) = {δ}_{1} + \frac{{δ}_{2} - {δ}_{1}}{1 + Exp ( \frac{{a}_{d} ( x - d )}{d} )}$$

where,
δ₁—indicates the value of the disorientation angle of the substrate present in the laser region,
δ₂—indicates the value of the disorientation angle of the substrate present in the light guide region,
d—indicates the width of the aperture,
x—indicates the spatial coordinate in the aperture between the laser and the light guide,
a_{d}—indicates a coefficient specifying the change profile, comprised in range of 3 to 7.

Preferably, the system is characterised in that the disorientation of the gallium nitride substrate in the light guide region, 4 in FIG. 1, is higher than the basic disorientation of the gallium nitride substrate and is defined by equation:

$${δ}_{2} > \frac{{a}_{1} {δ}_{1} + 0.05 {a}_{2} - 20}{0.43 {a}_{1}}$$

where,
δ₁—indicates the value of the disorientation angle of the substrate present in the laser region,
δ₂-indicates the value of the disorientation angle of the substrate present in the light guide region,
a₁ and a₂—indicate parameters depending on the growth conditions of the layers and describing the linear approximation of the relationship between the emission wavelength of the structure and the disorientation angle δ₁.

Preferably, the system is characterised in that the width of the aperture between the laser mirror and the light guide entry window, FIG. 2, is defined by equation:

$$d < ( 1.5 {w}_{m} - 0.5 {w}_{l} ) / Tan ( \frac{2 λ}{π {w}_{l}} )$$

where,
d—indicates the width of the aperture,
wₗ and wₘ—indicate the optical mode width in the transverse direction in the laser region and in the light guide region, respectively,
λ—indicates the emission wavelength of the laser.

Preferably, the system is characterised in that the aperture walls on the side of the laser are coated with optical layers with light reflection coefficient values in range of 0.1-100%.

Preferably, the system is characterised in that the aperture walls od the side of the light guide are coated with optical layers with light reflection coefficient values below 1%.

Preferably, the system is characterised in that the light guide has a bent shape—FIG. 3.

Preferably, the system is characterised in that, on the gallium nitride substrate at least two lasers with light guides are arranged, wherein the light guides are combined into one main light guide—FIG. 4.

A local change in substrate disorientation can be achieved through multilevel photolithography in a thick positive photoresist and dry etching using the reactive ion etching method—FIG. 5. According to the invention, the region with increased disorientation takes a shape similar to, but larger than, the future light guide, for example, a rectangle. After spin coating the photoresist on the GaN substrate, multi-level photolithography is performed, that is, illumination of the photoresist with a spatially variable dose of light, the dose having more than two possible values. A possible solution is a linear light dose profile in the direction of the shorter side of the rectangle, where the grayscale corresponds to the dose of light (white—the highest dose, black—the lowest dose). This type of pattern, with properly selected process parameters, leads to the formation of a three-dimensional slope shape after development of the photoresist. Next, the substrate with the formed photoresist is subjected to dry etching process using the reactive ion etching method, which transfers the three-dimensional pattern onto the GaN substrate surface. The value of the disorientation angle of the region should be higher compared to the disorientation angle of the GaN substrate. This change is intended to increase the energy gap of quantum wells in the light guide region, and thus to reduce absorption at the wavelength of laser emission. According to the invention, the relationship between the disorientation in the light guide region and the disorientation of the substrate has the form defined by equation I:

$${δ}_{2} > \frac{{a}_{1} {δ}_{1} + 0.05 {a}_{2} - 20}{0.43 {a}_{1}}$$

where δ₁ is the value of the disorientation angle of the substrate present in the laser region, δ₂ is the value of the disorientation angle of the substrate present in the light guide region, whereas a₁ and a₂ are parameters depending on the growth conditions of the layers and describing the linear approximation of the relationship between the emission wavelength, A, expressed in nm, of the structure and the disorientation angle δ₁, estimated in a range of typical substrate disorientation of 0.4° to 1° using the equation II:

$$λ = {a}_{1} {δ}_{1} + {a}_{2}$$

Next, the structure growth is carried out using the metalorganic epitaxy method. The cladding layers are made of gallium-aluminium nitride AlₓGa₁₋ₓN, for which x is comprised in range of 0.05 to 0.12 and with a thickness of 0.5 μm to 5 μm. The bottom cladding layer is doped with silicone on a level of 5×10¹⁸ cm⁻³. The upper cladding layer is typically doped with magnesium on a level of 5×10¹⁸ cm⁻³ to 1×10¹⁹ cm⁻³. The light guide layers are typically made of gallium nitride with a thickness of 0.05 μm to 0.15 μm.

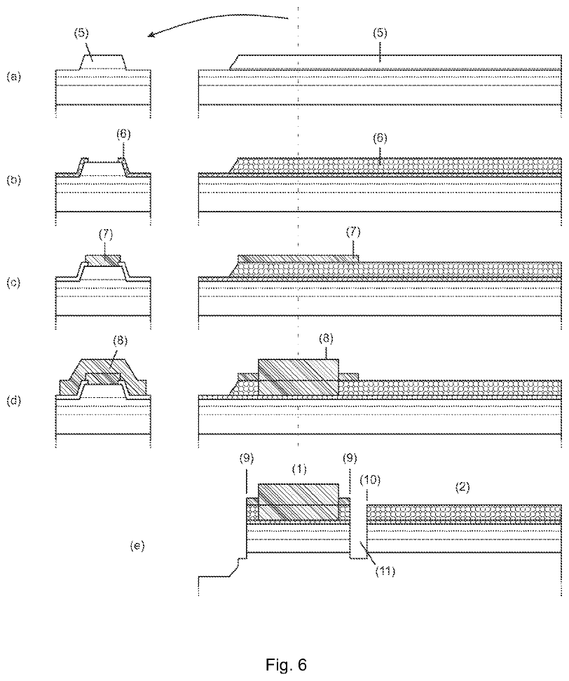

The bottom light guide layer can be doped with silicone and the upper light guide layer can be doped with magnesium. Both light guide layers can also be non-doped or only a part of their thickness can be doped. The electrode blocking layers, in case of diodes emitting in range of 390-550 nm, are made of AlₓGa₁₋ₓN, for which x is comprised in range of 0 to 0.2. The layer constituting the light-generating active region can consist of a single InₓGa₁₋ₓN quantum well, for which x is comprised in range of 0 to 0.3, and has a thickness of 2 nm to 10 nm, as well as a few quantum wells with a similar structure, separated by barriers of GaN or InₓGa₁₋ₓN with In content lower than that of the quantum well. As the final layer, above the upper cladding layer, a subcontact layer is obtained, which is highly doped with magnesium on a level of 5×10¹⁹ cm⁻³ to 1×10²⁰ cm⁻³. After the epitaxial growth, a series of processes is carried out in order to manufacture the laser diode—FIG. 6. The main technological steps include: forming a ridge defining the resonant cavity (contrast of the refractive index) along the instrument and the shape of the light guide, using photolithography and reactive ion etching, embedding a layer isolating the regions which are not intended to be electrically excited (insulation made of e.g. SiO₂ or SiN), embedding an electrical contact on the p-type side, and embedding an electrical contact with a larger area, enabling wire electrical connections. After manufacturing of the laser is completed, another process of photolithography and etching is carried out, defining the mirrors of the laser resonant cavity and the light guide entry window—FIG. 6e. In order to reduce the coupling losses between the laser and the light guide, it is important to choose the aperture width between the light guide entry window and the closest mirror of the laser, FIG. 2. The width of the aperture between the laser and the light guide (parameter d) depends on the epitaxial structure of the laser and the light guide and is defined by equation III:

$$d < ( 1.5 {w}_{m} - 0.5 {w}_{l} ) / Tan ( \frac{2 λ}{π {w}_{l}} )$$

where d is the width of the aperture, wₗ and wₘ are the optical mode width in the transverse direction in the laser region and in the light guide region, respectively, determined as a decrease in intensity in the light profile equal to 1/(e²), λ is the emission wavelength of the laser.
In order to reduce the coupling losses between the laser and the light guide, the disorientation change profile in the region between the laser and the light guide is also important. The local disorientation δₗₒₖ in the aperture region should change in a continuous and smooth manner. The local disorientation δₗₒₖ between the laser and the light guide depends on the disorientation of the substrate, disorientation of the light guide region and the width of the aperture, and is defined by equation IV:

$${δ}_{lok} ( x ) = {δ}_{1} + \frac{{δ}_{2} - {δ}_{1}}{1 + Exp ( \frac{{a}_{d} ( x - d )}{d} )}$$

where x is a spatial coordinate inside the aperture between the laser and the light guide, wherein x=0 for the laser mirror, and a_{d} is a coefficient specifying the profile change comprised in range of 3 to 7.

The invention enables manufacturing a light guide not only in a form of a straight stripe, but also allows a change in direction of the light propagation by bending the light guide (FIG. 3), as well as combining the light emitted from several lasers using a light guide comprising multiple entry windows (FIG. 4).

The object of the invention in the embodiments is shown on a drawing, in which FIG. 1 shows a diagram illustrating the position of the laser, the light guide, and the region with increased disorientation on a GaN substrate, FIG. 2 shows the cross-sectional side view of the laser and light guide system, FIG. 3 shows a diagram illustrating system of a laser and a light guide with a bent shape, which allows changing the direction of light propagation in relation to the axis of the laser, FIG. 4 shows a diagram illustrating a system of multiple lasers, the signal of which is coupled to the light guide branches, connected to each other, having a common output.

The method according to the invention in the embodiment has been described in more detail with reference to the drawing, in which FIG. 5 shows a diagram of forming a local change in disorientation in the direction “a” and in the light guide region, FIG. 6 shows a diagram of manufacturing the laser and light guide.

### LIST OF INDICATIONS USED

1—laser,
2—light guide,
3—gallium nitride substrate,
4—region with increased disorientation,
5—laser ridge,
6—layer of insulating material,
7—layer with p-type electrical conductivity,
8—fields/layers made of gold,
9—laser mirrors,
10—light guide entry window,
11—aperture.

### EXAMPLE 1

The method of manufacturing a system of a laser 1 and a light guide 2 coupled to it begins with structuring a gallium nitride bulk substrate 3 (FIG. 1). A gallium nitride substrate 3 with disorientation δ₁ equal to 0.6° in the crystallographic direction M has been chosen. Initial tests allowed determining the values of a₁ and a₂ coefficients in equation (I) as −29*1/° and 465 nm, respectively. A pattern for multilevel photolithography was prepared, leading to an increase in disorientation of the substrate to a value of 52=14°. At the same time, the pattern assumes a smooth change in disorientation between the future region of the laser 1 and the light guide 2 according to the relationship defined by equation (IV) for the parameter a_{d} equal to 5.

First, a 5 μm thick layer of positive photoresist is applied on the gallium nitride substrate 3 (FIG. 5). Next, the positive photoresist layer is illuminated with a spatially variable dose of light accordingly, which leads to obtaining a slope with increased disorientation after development of the photoresist. A three-dimensional shape of the photoresist is obtained, which is transferred to the substrate by dry etching using the reactive ion etching method in argon-chlorine plasma. After preparing the substrate, epitaxial growth is carried out using the metalorganic vapour phase epitaxy method. First, a 1.7 μm thick Al_{0.07}Ga_{0.93}N bottom cladding layer is applied, doped with silicone at the level of 5×10¹⁸ cm⁻³. Next, a 0.1 μm thick In_{0.05}Ga_{0.95}N bottom light guide layer is applied, doped with silicone at the level of 2×10¹⁸ cm⁻³. Next, a light-generating active region is applied, comprising two 2 nm thick In_{0.09}Ga_{0.91}N quantum wells surrounded by 8 nm thick barriers of gallium nitride, wherein the active region is intentionally non-doped. Next, a 0.1 μm thick In_{0.05}Ga_{0.95}N upper light guide layer is applied, doped with magnesium at the level of 2×10¹⁸ cm⁻³, wherein, within it a 20 nm thick Al_{0.12}Ga_{0.88} layer is also formed, doped with magnesium at the level of 5×10¹⁹ cm⁻³ at a distance of 50 nm from the interface between the active region and the upper light guide layer. Next, a 0.5 μm thick Al_{0.07}Ga_{0.93}N upper cladding layer is applied, doped with magnesium at the level of 1×10¹⁹ cm⁻³. Finally, a subcontact layer is applied, highly doped with magnesium at the level of 7×10¹⁹ cm⁻³, and having a thickness of 50 nm.

Next, processing of the structure is carried out—FIG. 6. First, a positive photoresist is applied and photolithography is carried out, defining the shape of a ridge 5 of the future laser 1 and the light guide 2 in a form of a 2 μm wide stripe with its longer axis oriented along the crystallographic direction M. Next, dry etching is carried out by means of active Ar and Cl ions, to a depth of 520 nm, FIG. 6a. Next, ridge 5 is formed passing from the flat part of the gallium nitride substrate 3 to the region 4 with increased disorientation. Next, a layer of insulating material 6, in a form SiO₂ with a thickness of 200 nm, is deposited on the surface of the entire “crystal” (FIG. 6b). Next, an ultrasonic washing procedure is performed, which removes the photoresist along with the insulation present on it, leaving an exposed fragment of the subcontact layer with a length of 900 μm on top of the ridge 5. Next, another photolithography is carried out, defining the windows within and around the uninsulated region, and then a 200 nm thick layer of gold (Au) 8 is deposited, which constitutes an electrical contact on the side of the layer 7 with p-type electrical conductivity, and another washing procedure is performed, removing the photoresist and fragments of Au layer 8 which are deposited on the photoresist—FIG. 6c. Next, another photolithography process is carried out, defining windows with a shorter length and greater width than the existing Au layers 8, and then another 500 nm thick Au layer 8 is deposited. After another washing process, rectangular layers of Au 8 are left, with a width of 200 μm and length of 800 μm, enabling the subsequent formation of an electrical connection using wires (ball-wedge method)—FIG. 6d. Next, another photolithography process is carried out using a 5 μm thick negative photoresist, to define the position of the laser mirrors 9 and the light guide entry window 10. The width of the aperture 11 is chosen based on equation (Ill) and has a value of 1.8 μm. Next, the whole “crystal” is subjected to an etching process using active Ar and Cl ions to a depth of 4 μm, and material outside the laser 1 and the light guide 2 is removed, simultaneously forming the aperture 11 between the laser 1 and the light guide 2—FIG. 6e. At the end, a 500 nm thick Au layer 8 is deposited on the bottom side of the sample, thus forming an n-type electrical contact.

Next, the laser 1 and light guide 2 system is mounted in a copper housing using a thin layer of SnPb (tin-lead) solder. The burn-in process is carried out at a temperature of 200° C. to permanently connect the laser 1 and light guide 2 system to the support. Next, using the ball-wedge method, an electrical contact is formed with the material of the upper contact.

### EXAMPLE 2

An embodiment of the present invention is a laser 1 and light guide 2 system, wherein the laser mirrors 9 and the light guide entry window 10 are coated with layers changing their reflection coefficient. The laser 1 and light guide 2 system is manufactured in a manner similar to that of Example 1, wherein, after the formation of mirrors 9 of the laser 1, the laser guide window 10, and the aperture 11 is completed, a photolithography process is carried out, covering the majority of the surface of laser 1, exposing only the mirror 9 on the side of the light guide entry window 10. Next, a deposition process of an 85 nm thick SiO₂ dielectric layer is carried out, lowering the reflection coefficient of the mirror 9. Next, the photoresist is removed and another photolithography process is carried out, exposing only the mirror 9 further from the light guide window 10. Next, a Bragg mirror type dielectric multilayer is deposited, increasing the reflection coefficient of the rear mirror 9 of the laser 1. 5 repetitions of alternating deposition of SiO₂ and Ta₂O₅ double layer, with a thickness of 65 nm and 29 nm, respectively, are carried out. Next, the photoresist is removed and another photolithography process is carried out, exposing only the light guide window 10. Next, a deposition process of an 81 nm thick SiO₂ dielectric layer is carried out, lowering the reflection coefficient of the mirror 9 to a value below 1%. After these layers have been deposited, mounting of the laser 1 and light guide 2 system is continued, similarly to Example 1.

### EXAMPLE 3

Another embodiment of the present invention is a laser 1 and light guide 2 system, wherein the light guide 2 has a bent shape enabling changing the propagation direction of light emitted by the laser 1—FIG. 3. The laser 1 and light guide 2 system is manufactured similarly to Example 1, wherein the region 4 with increased disorientation and the ridge 5 in the light guide 2 region have a bent shape. In the vicinity of the laser 1, both the region 4 with increased disorientation and the ridge 5 are arranged parallelly to the longer axis of the laser 1. They are bent accordingly to an arc with a radius of 600 μm, at a distance of 500 μm from the mirror 9 of laser 1, achieving a change in direction of 300 relative to the initial direction of the light guide 2. Further, the region 4 with increased disorientation and the ridge 5 maintain a constant direction at a distance of 600 μm.

### EXAMPLE 4

Another embodiment of the present invention is a system of three lasers 1 coupled to the same light guide 2, wherein the light guide 2 comprises separate branches for each laser 1, which are connected to each other, leading to a common end of the light guide 2. The lasers 1 and light guide 2 system is manufactured similarly to Example 1 and/or 2, wherein, during each manufacturing steps, the three lasers 1 are manufactured simultaneously, and the light guide 2 is shaped to collect light from all three lasers 1—FIG. 4. The individual branches of the light guide 2, guiding the light emitted by each laser 1, are connected using bends in the region 4 with increased disorientation and the ridge 5 with a radius of 600 μm.

1. A method for manufacturing a laser and light guide system comprising the following steps:
a) a gallium nitride bulk substrate is formed, after which regions with increased disorientation in relation to their surroundings are defined on the gallium nitride substrate,
b) a bottom cladding layer with n-type electrical conductivity is deposited,
c) a bottom light guide layer with n-type electrical conductivity is deposited,
d) a light-emitting layer is deposited, comprised of a single or a multiple quantum well made of a compound with a formula of InₓGa₁₋ₓN,
e) a non-doped upper light guide layer is deposited,
f) an electron blocking layer with p-type electrical conductivity is deposited,
g) an upper light guide layer with p-type electrical conductivity is deposited,
h) an upper cladding layer with p-type electrical conductivity is deposited,
i) a subcontact layer with p-type electrical conductivity is deposited,
j) a spatial structure of a light guide in a shape of a ridge is formed,
k) an aperture separating the laser and the light guide is formed, forming one of the laser mirrors, characterised in that the light guide is formed out of the same layers as the laser structure, whereas the quantum wells in the light guide region comprise at least 3.5 mol % less indium compared to the laser region, and the optical absorption of laser light in the light guide is lower than 12 cm⁻¹.

2. The method according to claim 1, characterised in that the disorientation profile of the gallium nitride substrate in the aperture region, between the laser mirror and the light guide entry window, is defined by equation:
$${δ}_{lok} ( x ) = {δ}_{1} + \frac{{δ}_{2} - {δ}_{1}}{1 + Exp ( \frac{{a}_{d} ( x - d )}{d} )}$$
where,
δ₁—indicates the value of the disorientation angle of the substrate present in the laser region,
δ₂—indicates the value of the disorientation angle of the substrate present in the light guide region,
d—indicates the width of the aperture,
x—indicates the spatial coordinate in the aperture between the laser and the light guide,
a_{d}—indicates a coefficient specifying the change profile, comprised in range of 3 to 7.

3. The method according to any of the claims 1-2, characterised in that the disorientation of the gallium nitride substrate in the light guide region is higher than the basic disorientation of the gallium nitride substrate and is defined by equation:
$${δ}_{2} > \frac{{a}_{1} {δ}_{1} + 0.05 {a}_{2} - 20}{0.43 {a}_{1}}$$
where,
δ₁—indicates the value of the disorientation angle of the substrate present in the laser region,
δ₂—indicates the value of the disorientation angle of the substrate present in the light guide region,
a₁ and a₂—indicate parameters depending on the growth conditions of the layers and describing the linear approximation of the relationship between the emission wavelength of the structure and the disorientation angle δ₁ (λ=a₁δ₁+a₂).

4. The method according to any of the claims 1-3, characterised in that the width of the aperture between the laser mirror and the light guide entry window is defined by equation:
$$d < ( 1.5 {w}_{m} - 0.5 {w}_{l} ) / Tan ( \frac{2 λ}{π {w}_{l}} )$$
where,
d—indicates the width of the aperture,
wₗ and wₘ—indicate the optical mode width in the transverse direction in the laser region and in the light guide region, respectively,
λ—indicates the emission wavelength of the laser.

5. The method according to any of the claims 1-4, characterised in that the aperture walls on the side of the laser are coated with optical layers with light reflection coefficient values in range of 0.1-100%.

6. The method according to any of the claims 1-4, characterised in that the aperture walls on the side of the light guide are coated with optical layers with light reflection coefficient values below 1%.

7. The method according to claims 1-4, characterised in that the light guide having a bent shape is formed.

8. The method according to claims 1-4, characterised in that, on the gallium nitride substrate, a structure is formed comprising at least two lasers with light guides, wherein the light guides are combined into one main light guide.

9. A laser and light guide system comprising, sequentially, a structured gallium nitride bulk substrate, on which regions with increased disorientation in relation to their surroundings are defined, a bottom cladding layer with n-type electrical conductivity, a bottom light guide layer with n-type electrical conductivity, a light-emitting layer comprised of a single or a multiple quantum well made of a compound with a formula of InₓGa₁₋ₓN, a non-doped upper light guide layer, an electron blocking layer with p-type electrical conductivity, an upper light guide layer with p-type electrical conductivity, an upper cladding layer with p-type electrical conductivity, a subcontact layer with p-type electrical conductivity, a spatial structure of a light guide in a shape of a ridge, an aperture separating the laser and the light guide, forming one of the laser mirrors, characterised in that the light guide (2) comprises the same layers as the laser (1) structure, wherein the quantum wells in the light guide (2) region comprise at least 3.5 mol % less indium compared to the laser (1) region, and the optical absorption of laser (1) light in the light guide (2) is lower than 12 cm⁻¹.

10. The system according to claim 9, characterised in that the disorientation profile of the gallium nitride substrate (3) in the aperture (11) region, between the laser (1) mirror (9) and the light guide entry window (10), is defined by equation:
$${δ}_{lok} ( x ) = {δ}_{1} + \frac{{δ}_{2} - {δ}_{1}}{1 + Exp ( \frac{{a}_{d} ( x - d )}{d} )}$$
where,
δ₁—indicates the value of the disorientation angle of the substrate present in the laser (1) region,
δ₂—indicates the value of the disorientation angle of the substrate present in the light guide (2) region,
d—indicates the width of the aperture (11),
x—indicates the spatial coordinate in the aperture (11) between the laser (1) and the light guide (2),
a_{d}—indicates a coefficient specifying the change profile, comprised in range of 3 to 7.

11. The system according to any of the claims 9-10, characterised in that the disorientation of the gallium nitride substrate (3) in the light guide (2) region is higher than the basic disorientation of the gallium nitride substrate (3) and is defined by equation:
$${δ}_{2} > \frac{{a}_{1} {δ}_{1} + 0.05 {a}_{2} - 20}{0.43 {a}_{1}}$$
where,
δ₁—indicates the value of the disorientation angle of the substrate present in the laser (1) region,
δ₂—indicates the value of the disorientation angle of the substrate present in the light guide (2) region,
a₁ and a₂—indicate parameters depending on the growth conditions of the layers and describing the linear approximation of the relationship between the emission wavelength of the structure and the disorientation angle δ₁ (λ=a₁δ₁+a₂).

12. The system according to any of the claims 9-11, characterised in that the width of the aperture (11) between the laser (1) mirror (9) and the light guide entry window (10) is defined by equation:
$$d < ( 1.5 {w}_{m} - 0.5 {w}_{l} ) / Tan ( \frac{2 λ}{π {w}_{l}} )$$
where,
d—indicates the width of the aperture (11),
wₗ and wₘ—indicate the optical mode width in the transverse direction in the laser (1) region and in the light guide (2) region, respectively,
λ—indicates the emission wavelength of the laser (1).

13. The system according to any of the claims 9-12, characterised in that the aperture (11) walls on the side of the laser (1) are coated with optical layers with light reflection coefficient values in range of 0.1-100%.

14. The system according to any of the claims 9-12, characterised in that the aperture (11) walls on the side of the light guide (2) are coated with optical layers with light reflection coefficient values below 1%.

15. The system according to claims 9-12, characterised in that the light guide has a bent shape.

16. The system according to claim 9, characterised in that, on the gallium nitride substrate (3), at least two lasers (1) with light guides (2) are arranged, wherein the light guides (2) are combined into one main light guide (2).
